(19) United States
(12) Patent Application Publication
(10) Pub. No.: US 2017/0040199 A1
(43) Pub. Date: Feb. 9, 2017

(54) SEMICONDUCTOR MANUFACTURING APPARATUS AND METHOD FOR MANUFACTURING SEMICONDUCTOR INTEGRATED CIRCUIT DEVICE

(71) Applicant: Renesas Electronics Corporation, Tokyo (JP)

(72) Inventors: Kenji TSUJI, lbaraki (JP); Kazuyuki OZEKI, lbaraki (JP)

(21) Appl. No.: 15/226,391

(22) Filed: Aug. 2, 2016

(30) Foreign Application Priority Data
Aug. 3, 2015 (JP) 2015-153304

(51) Int. Cl. H01L 21/683; H01L 21/027; H01L 21/67; H01L 21/311; C23C 14/34; H01L 21/306; H01L 21/02; C23C 16/50; H01J 37/32; H01L 21/687; H01L 21/308

(52) U.S. Cl. CPC H01L 21/6833; H01L 21/6838; H01L 21/68785; H01L 21/68735; H01L 21/0274; H01L 21/67069; H01L 21/31138; H01L 21/31144; H01L 21/3081; H01L 21/30604; H01L 21/02164; H01L 21/02595; H01L 21/02532; C23C 16/50; H01J 37/32009; C23C 14/34; H01J 2237/334

(57) ABSTRACT

To improve reliability of a semiconductor manufacturing apparatus using plasma. Moreover, to improve reliability of a semiconductor integrated circuit device and to reduce a fraction defective. A gap between a suction head of an electrostatic chuck and a protection ring is made smaller than a mean free path of molecules of the plasma.

### CLAIM OF PRIORITY

The present application claims priority from Japanese Patent application serial no. 2015-153304, filed on Aug. 3, 2015, the content of which is hereby incorporated by reference into this application.

### BACKGROUND OF THE INVENTION

Field of the Invention

The present invention relates to a semiconductor manufacturing apparatus and a method for manufacturing a semiconductor integrated circuit device that uses the apparatus, and in particular, to a semiconductor manufacturing apparatus using plasma.

Description of the Related Art

An electrostatic chuck for fixing a semiconductor wafer onto a stage (sample stand) by means of electrostatic force is widely used in semiconductor manufacturing apparatuses such as a dry etching apparatus, a CVD apparatus (CVD: Chemical Vapor Deposition), and a sputtering apparatus in semiconductor manufacturing lines. Moreover, these days, also in many semiconductor manufacturing apparatuses accompanied by a process in vacuum, such as an ion implanter, an ashing apparatus, and a wafer test apparatus, the electrostatic chuck has been widely adopted.

Among these semiconductor manufacturing apparatuses, especially the semiconductor manufacturing apparatuses using plasma, such as the dry etching apparatus and the CVD apparatus, have faced a problem of improving corrosion resistance of the electrostatic chucks against plasma, and therefore, row materials of the electrostatic chuck with higher durability and development of their structures are being furthered.

As a background art regarding the structure of the electrostatic chuck, there is a technology as in Patent document 1, for example. Patent document 1 discloses an “electrostatic chuck such that a slot of a depth less than or equal to a mean free path of used gas at a filling pressure is processed on a plane of a chuck main body that adjoins a sample substrate.”

[Patent document 1] Japanese Patent Application Laid-Open No. Hei 9(1997)-219442

Although in the conventional dry etching apparatus, a surface of an electrostatic chuck is covered (protected) with a semiconductor wafer during wafer processing by plasma and a side face of the electrostatic chuck is protected by a quartz ring, the plasma sneaks into a gap of the side face of the electrostatic chuck and the quartz ring, and does damage to a base material of the electrostatic chuck, an epoxy resin, and the quartz ring. As a result, there occur problems of a device trouble, dust emission, etc. caused by the epoxy resin being scraped and exfoliated. That is, improving reliability of the semiconductor manufacturing apparatus is being required. Moreover, when the base material consisting of aluminum etc. is scraped, even if no dust emission occurs, there is a risk that the wafer might be contaminated with the metal and the reliability might fall, which might lead to malfunction of the product. In particular, in a process of etching a gate electrode of a transistor, an interlayer insulation film, and wiring of aluminum etc., an influence of such metal contamination is large. That is, improving reliability of the semiconductor integrated circuit device and reducing the fraction defective are being required.

Other problems and new features will become clear from description and the accompanying drawings of this specification.

### SUMMARY OF THE INVENTION

According to one embodiment, a gap between the suction head of the electrostatic chuck and the protection ring is made smaller than a mean free path of molecules in plasma.

According to the one embodiment described above, the reliability of the semiconductor manufacturing apparatus using plasma, such as a dry etching apparatus, a CVD apparatus, and a sputtering apparatus, improves. Moreover, it becomes possible to improve reliability of the semiconductor integrated circuit device and to reduce a fraction defective.

### BRIEF DESCRIPTION OF THE DRAWINGS

FIG. 1A is a partial plan view of a semiconductor manufacturing apparatus according to one embodiment of the present invention;

FIG. 1B is an enlarged view of a section along a line A-A′ of FIG. 1A;

FIG. 1C is an enlarged view of a section along the line A-A′ of FIG. 1A;

FIG. 2A is a plan view of a protection ring of the semiconductor manufacturing apparatus according to one embodiment of the present invention;

FIG. 2B is an enlarged view of a section along a line D-D′ of FIG. 2A;

FIG. 2C is an enlarged view of the section along the line D-D′ of FIG. 2A;

FIG. 3 is a partial sectional view of the semiconductor manufacturing apparatus according to one embodiment of the present invention;

FIG. 4 is a partial sectional view of the semiconductor manufacturing apparatus according to one embodiment of the present invention;

FIG. 5 is a sectional view showing a part of a manufacturing process of a semiconductor integrated circuit device according to one embodiment of the present invention;

FIG. 6 is a sectional view showing a part of the manufacturing process of the semiconductor integrated circuit device according to the one embodiment of the present invention;

FIG. 7 is a sectional view showing a part of the manufacturing process of the semiconductor integrated circuit device according to the one embodiment of the present invention;

FIG. 8 is a plan view showing an overview of the semiconductor manufacturing apparatus according to the one embodiment of the present invention;

FIG. 9 is a sectional view showing an outline of a processing chamber of the semiconductor manufacturing apparatus according to the one embodiment of the present invention;

FIG. 10A is a partial plan view of the semiconductor manufacturing apparatus;

FIG. 10B is an enlarged view of a section along a line G-G′ of FIG. 10A; and

FIG. 10C is an enlarged view of the section along the line G-G′ of FIG. 10A.

### DETAILED DESCRIPTION OF THE PREFERRED EMBODIMENTS

Hereinafter, embodiments are described using drawings. Incidentally, in each drawing, the same reference numeral is given to the same constituent and a detailed explanation is omitted for an overlapping portion.

### First Embodiment

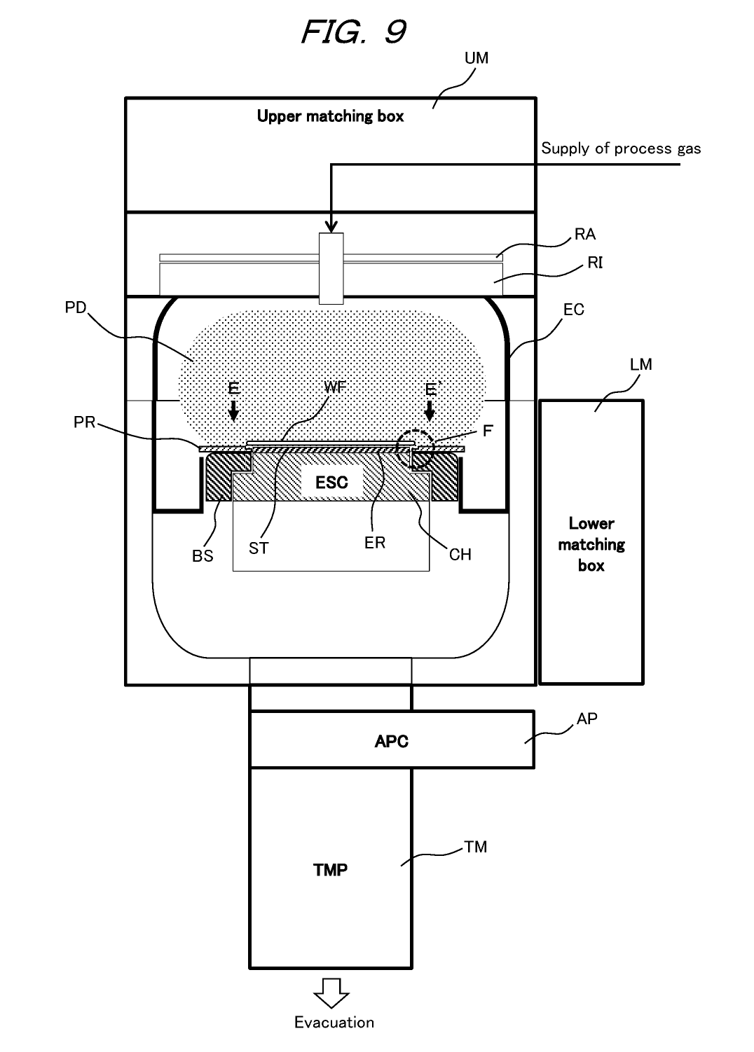

First, a semiconductor manufacturing apparatus in this embodiment is explained taking a dry etching apparatus as an example, using FIG. 8 and FIG. 9. FIG. 8 is a plan view showing an overview of a dry etching apparatus DE. Moreover, FIG. 9 is a sectional view showing an outline of an etching chamber EC in FIG. 8.

Referring to FIG. 8, the dry etching apparatus of this embodiment is configured with a loader/unloader LU for carrying a wafer into/out of the apparatus, an atmosphere transfer chamber AT in which the wafer is transferred in air, a vacuum transfer chamber VT in which the wafer is transferred in vacuum, three etching chambers that are treatment chambers of the wafer, and one ashing chamber AC.

The wafers that were set in the loader/unloader LU are carried into the vacuum transfer chamber VT one sheet by one sheet by a robot arm RA of the atmosphere transfer chamber AT. The wafer carried into the vacuum transfer chamber VT is carried into any one of three etching chambers EC by the transfer arm in the vacuum transfer chamber VT and is subjected to the dry etching processing by plasma in the etching chamber EC. Subsequently, the wafer is returned to the vacuum transfer chamber VT by the transfer arm, and is carried into the ashing chamber AC, and in the ashing chamber AC the ashing treatment is performed by oxygen (O₂) plasma.

After being returned again to the vacuum transfer chamber VT by the transfer arm, the wafer is collected into the loader/unloader LU through the atmosphere transfer chamber AT by the robot arm RA.

As is shown in FIG. 9, the etching chamber EC has an upper matching box UM mounted on its top and has a lower matching box LM installed on its side face. A high-frequency power outputted from an RF generator (not shown) is impedance matched by the upper matching box UM, subsequently is supplied to a high-frequency antenna RA, and generates plasma (electric discharge) PD by exciting a process gas supplied into the etching chamber EC. This is a plasma production system that is called inductively coupled plasma (ICP).

Moreover, a high-frequency power outputted from another RF generator (not shown) is impedance matched similarly by the lower matching box LM, subsequently is supplied to a lower electrode, i.e., an electrostatic chuck (ESC), and is used as RF bias for controlling incidence energy of ions in the plasma to the wafer.

A lower part of the etching chamber EC is coupled with a turbo molecular pump (TMP) TM through an automatic pressure control valve (APC) AP, and the turbo molecular pump (TMP) TM performs evacuation of the etching chamber EC.

A suction head CH that is a wafer mounting part of the electrostatic chuck (ESC) is formed by bonding a ceramic plate (stage ST) to a base material of aluminum (Al) serving as a base with an epoxy resin ER. Alumite treatment was performed on the aluminum base material for surface protection. Moreover, alumina ceramic (Al₂O₃) containing a dielectric is used for the ceramic plate serving as the stage ST.

A base BS and a protection ring PR are installed around the suction head CH so as to surround a circumference of the suction head CH. For a base material of the base BS and the protection ring PR, quartz that is high in electrical insulation and has little impurity content is used. For these base BS and protection ring PR, silicon (Si) may be used instead of quartz.

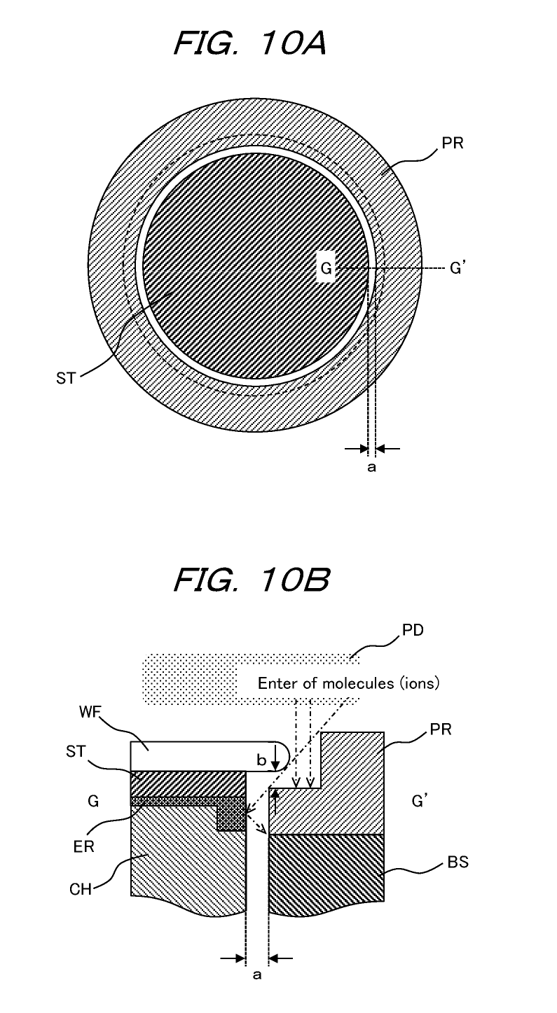

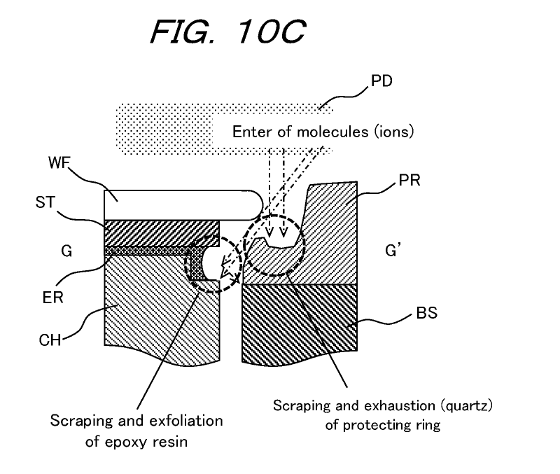

Next, the problem of sneak of the plasma into the gap between the electrostatic chuck and the protection ring is explained using FIG. 10A to FIG. 10C. FIG. 10A is an E-E′ arrow view in FIG. 9. Moreover, FIG. 10B and FIG. 10C are an enlarged view of a section F in FIG. 9 and an enlarged view of a section along a line G-G′ in FIG. 10A. Incidentally, in order to make it easy to recognize a spatial relationship of the constructional elements, FIG. 10A shows a state where no wafer is mounted, and FIG. 10B and FIG. 10C show a state where the wafer is mounted.

As shown in FIG. 10A, when the electrostatic chuck and the protection ring PR are seen from the above, the protection ring PR is installed so as to surround a circumference of the stage ST of the electrostatic chuck (suction head CH). There are various structures for the suction head CH. The suction head CH in this embodiment is such that the ceramic plate serving as the stage ST is bonded to the aluminum base material with the epoxy resin, as described above. Since an adhesion surface by this epoxy resin is extremely low in plasma resistant property, the protection ring PR is installed so that the plasma may not contact the adhesion surface.

As shown in FIG. 10A, there is a gap a between the stage ST and the protection ring PR, and this gap is about 0.15 mm. If a processing tolerance of ±0.02 mm of each of the stage ST and the protection ring PR is taken into consideration, this gap a will become the extent of 0.11 mm to 0.19 mm.

Moreover, as shown in FIG. 10B, when the wafer WF is mounted on the stage ST, there is a gap b between a back surface of the wafer WF and the protection ring PR, and this gap b is about 0.35 mm. Considering the processing tolerance of the protection ring PR of ±0.02, this gap b becomes the extent of 0.33 mm to 0.37 mm.

As shown in FIG. 10B, since both the gap a between a side face of the suction head CH and the stage ST that is its constructional element and the protection ring PR and the gap b between the back surface of the wafer WF and the protection ring PR are wide in width, which allow molecules (ions) in plasma PD to enter easily, an effect of preventing the epoxy resin ER that is a bonding surface of the suction head from contacting the plasma is low.

A reason why this gap a is wide is because an inner diameter of the protection ring PR is designed based on a mechanical alignment tolerance to an outer diameter of the suction head CH. That is, the configuration of the suction head CH and the protection ring PR is not a configuration that has taken characteristics of the plasma into consideration.

Moreover, a reason why the gap b is wide is that a height (thickness) of the protection ring PR is designed based on a mechanical alignment tolerance to heights (thicknesses) of the base ST and the suction head CH. The gap b does not have a configuration that takes the plasma characteristics into consideration, similarly with the gap a.

As a result, as shown in FIG. 10C, damages (scraping and exfoliation) of the epoxy resin ER by incidence of the molecules (ions) in the plasma occurs, there is a case where it may become a dust emission source, and may cause a minute abnormal discharge in a space generated by scraping, leading to an apparatus trouble, such as electrostatic suction error.

Moreover, since damages (scraping and exhaustion) by incidence of the molecules (ions) in the plasma occur also in the protection ring PR itself, there occurs a problem that the gaps on the rear surface side and the side face side of the wafer WF expand, and the plasma can more easily sneak into the gaps.

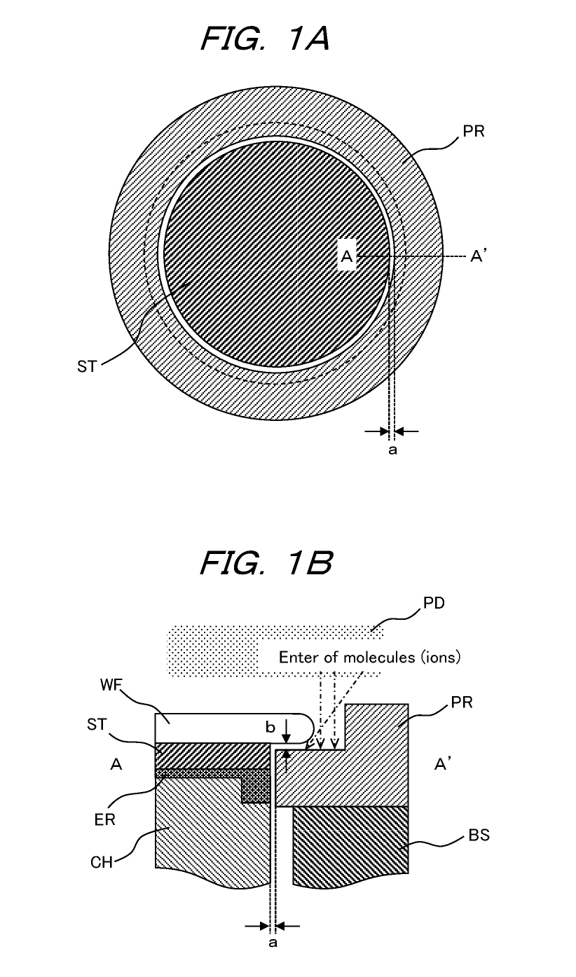

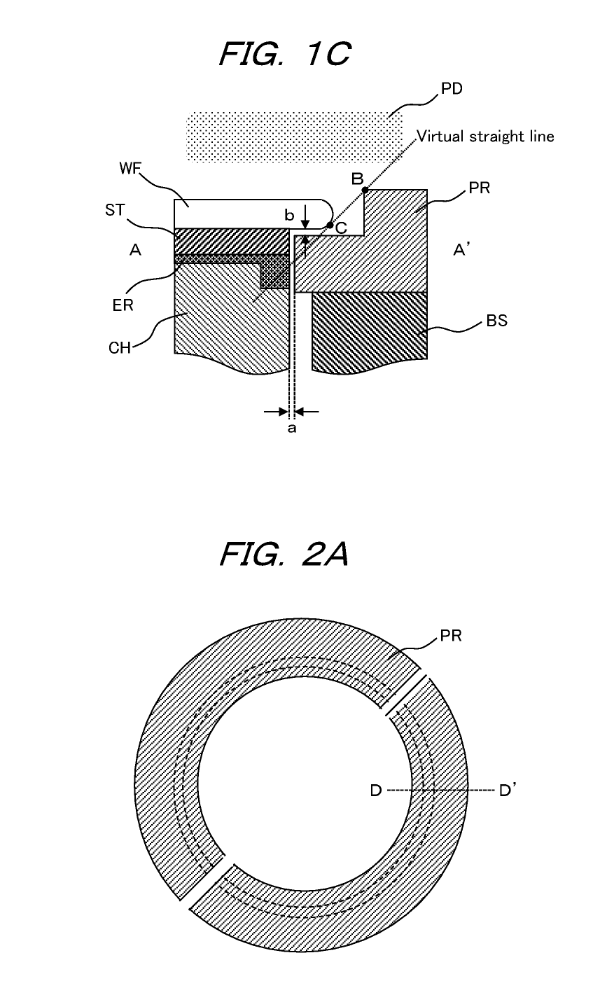

Configurations of the suction head CH and a circumference of the protection ring PR of this embodiment are explained using FIG. 1A to FIG. 1C. FIG. 1B and FIG. 1C are enlarged views of a section along a line A-A′ in FIG. 1A. Incidentally, in order to make it easy to recognize the spatial relationship of the constructional elements, FIG. 1A shows a state where no wafer is mounted, and FIG. 1B and FIG. 1C show a state where the wafer is mounted.

As shown in FIG. 1A, the gap a between the stage ST of the suction head CH and the protection ring PR is configured to be narrow in this embodiment. Specifically, this gap a is configured to become less than or equal to 0.05 mm. Incidentally, if the processing tolerance of ±0.02 mm of both the stage ST and the protection ring PR is taken into consideration, this gap a will have a tolerance limit of the extent of 0.01 mm to 0.09 mm. Although the gap may be less than or equal to 0.01 mm, in order to avoid breakage of the protection ring PR made of quartz caused by thermal expansion of the stage ST and the protection ring PR that accompanies a temperature rise by a process treatment (dry etching) of the wafer, it is desirable to provide a gap of at least approximately 0.01 mm in consideration of the thermal expansion of the stage ST and the protection ring PR.

Moreover, as shown in FIG. 1B, the gap b between the back surface of the wafer WF and the protection ring PR is configured to be narrow similarly when the wafer WF is mounted on the stage ST. Specifically, this gap b is configured to become less than or equal to 0.15 mm. Incidentally, if the processing tolerance of the protection ring PR of ±0.02 is taken into consideration, the extent of 0.13 mm to 0.17 mm will become a tolerance limit for this gap b. Although the tolerance limit may be less than or equal to 0.13 mm, it is desirable that at least when the wafer WF is mounted on the stage ST, a gap of such a degree that the protection ring PR and the wafer WF will not contact with each other be provided in consideration of assembling accuracy of the base BS and the protection ring PR.

Incidentally, the numerical values of the above-mentioned gap a and gap b are more suitable numerical values for acquiring the effect by this embodiment at the maximum, and are not limited to these numerical values. As shown in FIG. 1B, the gap a and the gap b should be configured just to have such a width that the molecules (ions) in the plasma PD cannot enter easily. That is, it is preferable that these gaps be set smaller than or equal to a mean free path of molecules (ions) in the plasma PD or be set to a width smaller than an amplitude of vibration of the molecules (ions) in the plasma PD.

Moreover, the protection ring PR has a side face (hereinafter called a lower region) whose end is close to the suction head CH and a side face (hereinafter called an upper region) whose end is more distant from the suction head CH than the lower region, as shown in FIG. 1B. Therefore, it is desirable that the above-mentioned gap b, i.e., a distance from the back surface of the wafer WF to a surface of the lower region of the protection ring PR be set smaller than the mean free path of the molecules (ions) in the plasma PD, or be set to a width smaller than the amplitude of vibration of the molecules (ions) in the plasma PD.

FIG. 1C shows a spatial relationship of the end B of the upper region of the protection ring PR on its uppermost surface facing the suction head CH, the end C of the wafer WF, and the epoxy resin ER using a virtual straight line that connects these parts. When the wafer WF is mounted on the suction head CH, assuming (drawing) the virtual straight line that connects the end B of the upper region of the protection ring PR on its uppermost surface facing the suction head CH, the end C of the wafer WF, and the epoxy resin, a configuration where this virtual straight line is obstructed by the lower region of the protection ring PR is realized.

Actions of this embodiment explained using FIG. 1A to FIG. 1C are explained. Although an interspace (gap) at which plasma discharge is difficult to generate in vacuum depends on a degree of vacuum and a composition of a gas kind, it is generally less than 0.1 mm. Moreover, an average distance (mean free path) over which molecules (ions) etc. in the plasma can advance without being blocked by scattering is 0.1 mm to 10 mm in a process zone of 3 Pa to 30 Pa. Therefore, if the interspace (gap) is less than or equal to this value, it will become difficult for the plasma discharge to generate in the gap, and become also difficult for the molecules (ions) in the plasma to enter.

Then, as described above, by decreasing the gap a between the stage ST of the suction head CH and the protection ring PR to 0.05 mm or less (when the processing tolerance is considered, 0.09 mm or less), it is possible to prevent the sneak of the plasma into between the suction head CH and the protection ring PR and generation of the plasma.

Moreover, by decreasing the gap b between the back surface of the wafer WF and the protection ring PR at the time of mounting the wafer WF on the stage ST to 0.15 mm or less (when the processing tolerance is considered, 0.17 mm or less), it is possible to further suppress the sneak of the plasma to the side face of the suction head CH.

As explained above, according to the configuration of this embodiment, by narrowing the gap between the electrostatic chuck (suction head) and the protection ring, or concretely by setting the gap to a dimension narrower than the mean free path of the gas molecules that become the plasma or than the width of vibration of the gas molecules in the plasma, it is possible to prevent the sneak of the plasma into the gap between the electrostatic chuck (suction head) and the protection ring and the generation of the plasma.

Moreover, by configuring the gap between the back surface of the wafer and the protection ring at the time of mounting the wafer on the electrostatic chuck (suction head) to be narrow, concretely, by setting the gap to a dimension narrower than the mean free path of the gas molecules that become the plasma, or than the amplitude of vibration of the gas molecules in the plasma, it is possible to inhibit the sneak of the plasma into the gap between the electrostatic chuck (suction head) and the protection ring and the generation of the plasma.

Because of these effects, a protection capability of the electrostatic chuck (suction head) of the protection ring can be improved considerably, and a device trouble and dust emission caused by the epoxy resin on a side face of the electrostatic chuck (suction head) being scraped and exfoliated can be reduced.

### Second Embodiment

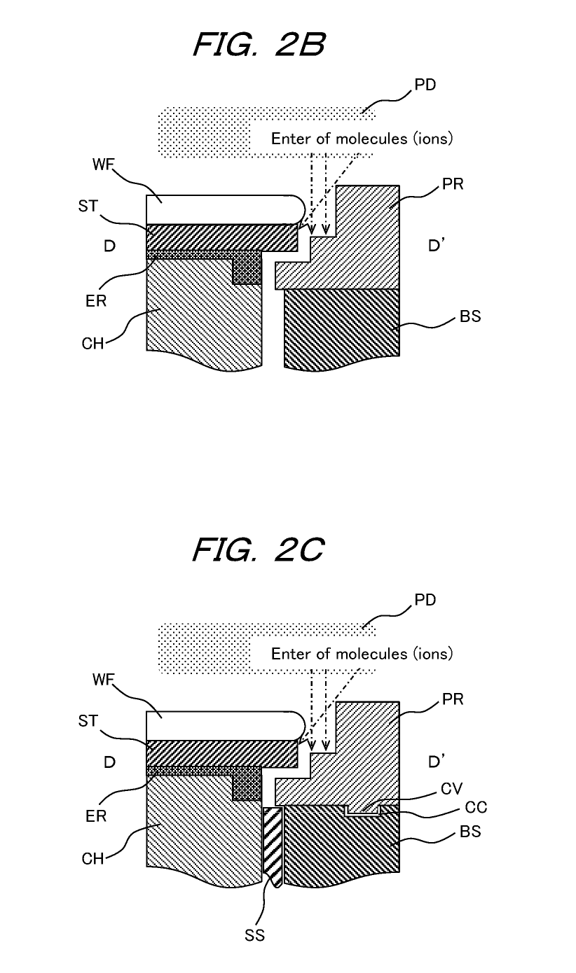

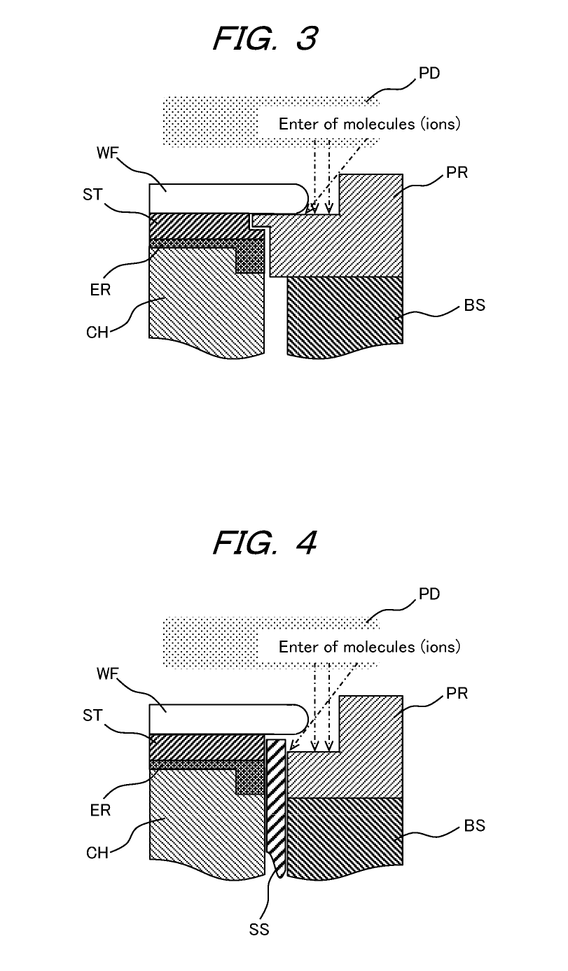

Configurations of the suction head CH and the circumference of the protection ring PR of this embodiment are explained using FIG. 2A to FIG. 4. FIG. 2B is an enlarged view of a section along a line D-D′ in FIG. 2A. However, in order to show a shape of the protection ring PR intelligibly, the wafer WF and the suction head CH (stage ST) are omitted in FIG. 2A. Moreover, FIG. 2C, FIG. 3, and FIG. 4 are modifications of FIG. 2B, respectively.

Referring to FIG. 2B, in the suction head CH of this embodiment, the ceramic plate, i.e., the stage ST, bonded to a position higher than the epoxy resin ER is formed to be wider than the aluminum base material. Moreover, the protection ring PR is formed to have multiple level differences according to a shape of the side face of the suction head CH.

Moreover, as shown in FIG. 2B, the protection ring PR has a side face whose end is close to the suction head CH (hereinafter, a lower region), a side face whose end is more distant from the suction head CH than the lower region (hereinafter, an intermediate region), and a side face whose end is more distant from the suction head than the intermediate region (hereinafter, an upper region). Furthermore, an end of the stage ST is disposed so that its end may be located between an end of the lower region and an end of the intermediate region.

By making the suction head CH and the protection ring PR have the above-mentioned structures, respectively, the gap between the electrostatic chuck (suction head CH) and the protection ring PR is configured to have a so-called labyrinth structure, which can prevent the sneak of the plasma into the gap of the electrostatic chuck (suction head CH) and the protection ring PR and the generation of the plasma in the gap. Moreover, by adopting the labyrinth structure, the distance (path) from the plasma PD to the epoxy resin ER becomes long, and therefore, the damage (scraping and exfoliation) of the epoxy resin by the plasma can be prevented effectively.

Although it is desirable that the distance between the suction head CH (stage ST) and each part of the protection ring PR be set to a dimension narrower than the mean free path of the gas molecules that become plasma or than the amplitude of vibration of the gas molecules in the plasma, since the plasma becomes difficult to sneak by adopting the labyrinth structure, the distance can be configured to be wide as compared to the gap a and the gap b of the first embodiment, and thereby the processing tolerances of the protection ring PR and the stage ST can be relaxed.

Incidentally, since the configuration of FIG. 2B takes a structure such that the gap between the electrostatic chuck (suction head CH) and the protection ring PR is step-wise and the stage ST of the suction head CH covers the gap, the protection ring PR cannot be removed at the time of maintenance inside the etching chamber EC in a state where the suction head CH (stage ST) is fixed inside the etching chamber EC. Then, as shown in FIG. 2A, by configuring the protection ring PR to have a structure that can be divided into at least two parts, it becomes possible to detach/attach the protection ring easily even in a state where the suction head CH (stage ST) is fixed in the etching chamber EC.

FIG. 2C shows a modification of this embodiment. When the protection ring PR is specified to have a block construction as shown in FIG. 2A, it poses a problem of accuracy in aligning the protection rings that were divided into multiple parts when being mounted on the base BS. When the alignment accuracy is poor, a portion where the gap between the electrostatic chuck (suction head CH) and the protection ring PR becomes wider than it should be will occur, which will make it easy for the plasma to sneak or for the plasma to generate. Therefore, for example, by providing a convex part CV in the lower part of the protection ring PR and providing a concave part CC is provided in the upper part of the base BS as shown in FIG. 2C, the alignment accuracy of the protection rings divided into the multiple parts can be improved and the gap between the electrostatic chuck (suction head CH) and the protection ring PR can be kept constant.

Moreover, in order to prevent dispersion of the gap between the electrostatic chuck (suction head CH) and the protection ring PR from being generated due to the assembling accuracy of the base BS, a separate spacer (sleeve) SS may be installed between the suction head CH and the base BS. This separate spacer (sleeve) SS is formed with the use of quartz, an alumina ceramic, silicon, a heat-resistant plastic such as a polyimide resin, or the like, for example.

FIG. 3 shows another modification of this embodiment. With the configuration of FIG. 2B, the gap between the electrostatic chuck (suction head CH) and the protection ring PR is step-wise, and the electrostatic chuck has a structure where the stage ST of the suction head CH covers the gap. Meanwhile, in the configuration of FIG. 3, a concave part is provided on the side face facing the protection ring PR of the stage ST, and further, the protection ring PR is formed with a part of the lower region protruded so that the part of the lower part of the protection ring PR may extend in the concave part of the stage ST. By adopting a configuration where a part of the protection ring is made to protrude so that a gap between the suction head CH and the protection ring PR may be covered up, the gap between the suction head CH and the protection ring PR can be made to have the labyrinth structure, which makes it possible to prevent the plasma from sneaking into the gap between the suction head CH and the protection ring PR and to prevent the plasma from being generated in the gap.

FIG. 4 shows further another modification of this embodiment. Instead of altering shapes of the electrostatic chuck (suction head CH) and the protection ring PR as shown in FIG. 2B, in the configuration of FIG. 4, the separate spacer (sleeve) SS is provided in the gap between the suction head CH and a set of the base BS and the protection ring PR. By adopting such a configuration, it is possible to prevent the plasma from sneaking into the gap between the suction head CH and the protection ring PR and to prevent the plasma from being generated in the gap. This separate spacer (sleeve) SS is formed using quartz, an alumina ceramic, silicon, and a heat-resistant plastic such as a polyimide resin, for example.

However, since aluminum (Al) is used for a base material of the suction head CH and its thermal expansion coefficient is large as compared with quartz, ceramics, etc., there is concern over breakage of the separate spacer (sleeve) SS by temperature rise at the time of the process treatment (dry etching) of the wafer. Therefore, thickness (dimension) setting of the separate spacer (sleeve) SS in consideration of the thermal expansion of the suction head CH becomes needed.

### Third Embodiment

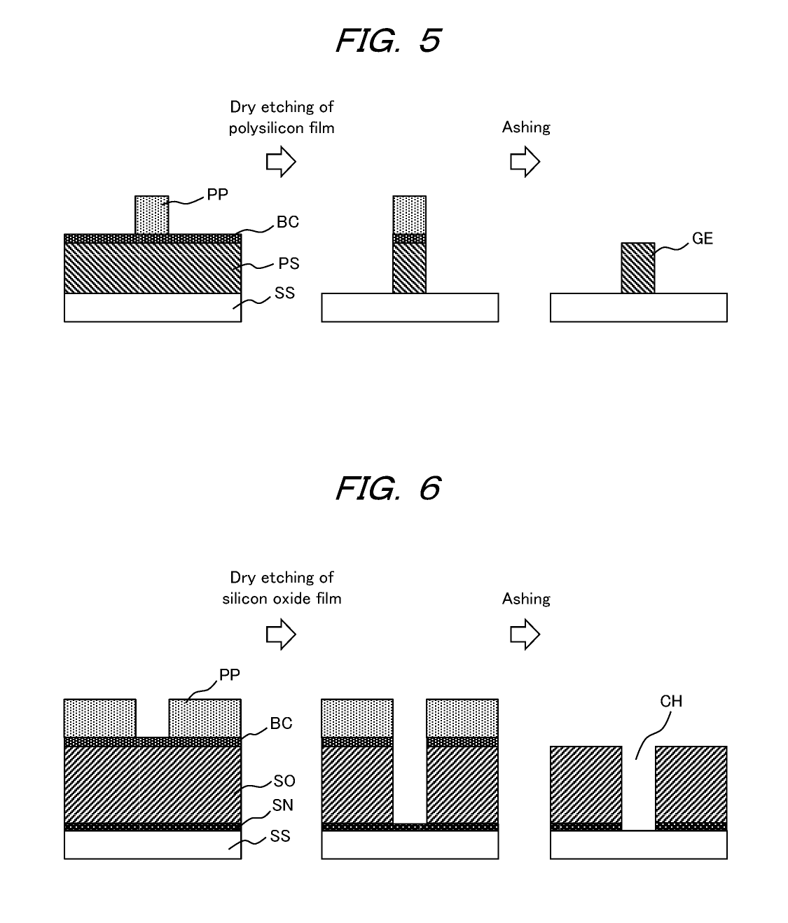

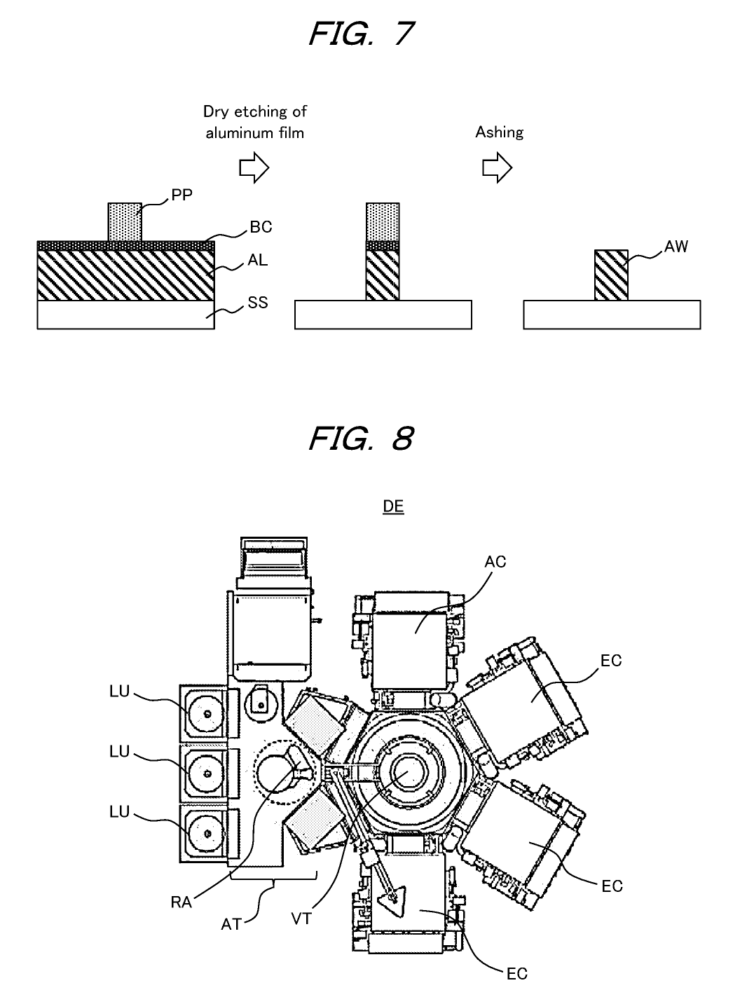

A method for manufacturing a semiconductor integrated circuit device in this embodiment is explained using FIG. 5 to FIG. 7. FIG. 5 shows a dry etching process of processing a gate electrode GE of a transistor. Moreover, FIG. 6 shows a dry etching process of processing a contact hole CH for conducting the lower layer wiring and the upper wiring in the silicon oxide (SiO₂) film that is an interlayer insulation film. FIG. 7 shows a dry etching process of processing aluminum wiring AW.

A dry etching process of a polysilicon film is explained with reference to FIG. 5. As shown in a left small figure of FIG. 5, a polysilicon film PS that becomes a target of dry etching is formed with a polysilicon film PS that is a film to be processed, an antireflection film (BARC) BC, and a photoresist pattern PP serving as an etching mask (mask pattern) at the time of the dry etching laminated sequentially from a lower layer on a silicon substrate SS.

The above-mentioned lamination structure is formed through the following process. First, the polysilicon film PS is formed on the principal plane of the silicon substrate SS that is a semiconductor substrate by a low-pressure CVD apparatus, and subsequently the antireflection film (BARC) BC is applied thereon by a coater. Incidentally, the antireflection film (BARC) BC may be omitted in accordance with a process condition or a target product (semiconductor integrated circuit device).

Next, a photoresist film is applied to the antireflection film (BARC) BC (when the antireflection film (BARC) BC is omitted, on the polysilicon film PS) by the coater. Then, a predetermined circuit pattern (here gate electrode pattern) is transferred to the photoresist film by photolithography to form the photoresist pattern (mask pattern) PP.

A lamination film structure containing the polysilicon film PS that was formed through the above-mentioned process is subjected to the dry etching processing by the dry etching apparatus explained in the first embodiment or the second embodiment. That is, the polysilicon film PS that is the film to be processed and the photoresist pattern (mask pattern) PP are subjected to the dry etching processing using a dry etching apparatus such that a distance from the stage ST of the suction head CH to the protection ring PR is smaller than the mean free path of molecules in plasma. (Center small figure of FIG. 5)

For dry etching of this polysilicon film PS, either a process gas that contains a mixed gas of sulfur hexafluoride (SF₆)/difluoromethane (CH₂F₂) as a main component or a process gas that contains hydrogen bromide (HBr) or chlorine (Cl₂) as a main component is used. Moreover, a mixed gas of chlorine (Cl₂)/oxygen (O₂)/helium (He) etc. are used for the dry etching of the antireflection film (BARC) BC.

Ashing processing with oxygen (O₂) plasma is performed using an ashing apparatus, whereby the photoresist pattern (mask pattern) PP and the antireflection film (BARC) BC that remained without being etched are removed to form the gate electrode GE.

A dry etching process of the silicon oxide film is explained with reference to FIG. 6. A silicon oxide film SO that is a target of the dry etching is formed, as shown in a left small figure of FIG. 6, with a silicon nitride SN that is an etching stopper film, the silicon oxide film SO that is a film to be processed, the antireflection film (BARC) BC, and the photoresist pattern PP serving as an etching mask at the time of dry etching (mask pattern) being laminated sequentially from a lower layer on the silicon substrate SS.

The above-mentioned lamination structure is formed through the following process. First, the silicon nitride SN is formed on a principal plane of the silicon substrate SS that is a semiconductor substrate by the plasma CVD apparatus, subsequently the silicon oxide film SO is formed by the plasma CVD apparatus similarly, and the antireflection film (BARC) BC is applied to the silicon oxide film SO by the coater. Incidentally, the antireflection film (BARC) BC may be omitted depending on the process condition or the target product (semiconductor integrated circuit device).

Next, a photoresist film is applied to the antireflection film (BARC) BC (when the antireflection film (BARC) BC is omitted, to the polysilicon film PS) by the coater. Then, a predetermined circuit pattern (here, a contact whole pattern) is transferred to the photoresist film by photolithography to form the photoresist pattern (mask pattern) PP.

The laminated film structure containing the silicon oxide film SO that was formed through the above-mentioned process is dry etched by the dry etching apparatus explained in the first embodiment or the second embodiment. That is, the silicon oxide film SO that is the film to be processed and the photoresist pattern (mask pattern) PP are subjected to the dry etching using the dry etching apparatus such that the distance from the stage ST of the suction head CH to the protection ring PR is smaller than the mean free path of the molecules in the plasma. (Center small figure of FIG. 6)

A process gas that contains a mixed gas of octafluorocyclopentene (C₅F₈)/oxygen (O₂)/argon (Ar) as a main component is used for the dry etching of this silicon oxide film SO. Moreover, a mixed gas of octafluorocyclobutane (C₄F₈)/oxygen (O₂)/argon (Ar) etc. are used for the dry etching of the antireflection film (BARC) BC. A mixed gas of difluoromethane (CH₂F₂)/oxygen (O₂)/argon (Ar) etc. are used for the dry etching of the silicon nitride SN.

Finally, the ashing processing by oxygen (O₂) plasma is performed using the ashing apparatus, and the photoresist pattern (mask pattern) PP and the antireflection film (BARC) BC that remained without being etched are removed to form the contact hole CH in the silicon oxide film SO.

A dry etching process of an aluminum film is explained with reference to FIG. 7. The aluminum film AL that is a target of dry etching is formed, as shown in a left small figure of FIG. 7, with the aluminum film AL that is a film to be processed, the antireflection film (BARC) BC, and the photoresist pattern PP serving as the etching mask at the time of dry etching (mask pattern) being laminated sequentially from a lower layer on the silicon substrate SS.

The above-mentioned lamination structure is formed through the following process. First, the aluminum film AL is formed on a principal plane of the silicon substrate SS that is a semiconductor substrate by a sputtering apparatus, and subsequently the antireflection film (BARC) BC is applied to the aluminum film AL by the coater. Incidentally, the antireflection film (BARC) BC may be omitted depending on the process condition or the target product (semiconductor integrated circuit device).

Next, a photoresist film is applied to the antireflection film (BARC) BC (when the antireflection film (BARC) BC is omitted, on the aluminum film AL) by the coater. Then, a predetermined circuit pattern (here aluminum wiring pattern) is transferred to the photoresist film by photolithography to form the photoresist pattern (mask pattern) PP.

The laminated film structure containing the aluminum film AL that was formed through the above-mentioned process is dry etched by the dry etching apparatus explained in the first embodiment or the second embodiment. That is, the dry etching processing is performed on the aluminum film AL that is the film to be processed and the photoresist pattern (mask pattern) PP using the dry etching apparatus such that the distance from the stage ST of the suction head CH to the protection ring PR is smaller than the mean free path of the molecules in the plasma. (Center small figure of FIG. 7)

A process gas that contains a mixed gas of chlorine (Cl₂)/boron trichloride (BCl₃) as a main component is used for dry etching of this aluminum film AL. Moreover, a mixed gas of sulfur hexafluoride (SF₆)/oxygen (O₂)/argon (Ar), etc. are used for dry etching of the antireflection film (BARC) BC.

Finally, the ashing treatment by oxygen (O₂) plasma is performed using the ashing apparatus, and the photoresist pattern (mask pattern) PP and the antireflection film (BARC) BC that remained without being etched are removed to form the aluminum wiring AW.

As explained above, according to this embodiment, in dry etching the polysilicon film that is the film to be processed, the silicon oxide film, and the aluminum film, the processing is performed using the dry etching apparatus such that the distance from the stage of the electrostatic chuck (suction head) explained in the first embodiment or the second embodiment to the protection ring is narrower (smaller) than the mean free path of the gas molecules that become plasma or than the amplitude of vibration of the gas molecules in the plasma. Thereby, the device trouble and the dust emission caused by the epoxy resin on the side face of the electrostatic chuck (suction head) being scraped and exfoliated can be reduced. As a result, malfunction of the product by the device trouble during the dry etching processing and lowering of product yield by a foreign substance can be suppressed.

Incidentally, although the semiconductor manufacturing apparatus was explained in the first embodiment to the third embodiment mainly using the example of the dry etching apparatus; as long as an apparatus has the same structures of the electrostatic chuck and the protection ring, the same effect can be obtained by the apparatus being modified to have the configuration explained in the each embodiment. For example, the electrostatic chuck can be applied also to a semiconductor manufacturing apparatus using plasma, such as a plasma CVD apparatus and a sputtering apparatus.

As described above, although the invention made by the present inventors was explained concretely based on the embodiments, the present invention is not limited to the embodiments, and it goes without saying that the invention can be altered variously within a range that does not deviates from its gist.

### LIST OF REFERENCE SIGNS

PR—Protection ring,
ST—Stage,
BS—Base,
ER—Epoxy resin (binder),
CH—Suction head,
PD—Plasma (Electric discharge),
WF—Wafer,
SS—Separate spacer (Sleeve),
CC—Concave part,
CV—Convex part,
SS—Silicon substrate
PS—Polysilicon film (Poly-Si),
BC—Antireflection film (BARC),
PP—Photoresist pattern (mask pattern),
GE—Gate electrode,
SN—Silicon nitride film (Si₃N₄).
SO—Silicon oxide film (5iO₂).
CH—Contact hole,
AL—Aluminum film (AL),
AW—Aluminum wiring,
DE—Dry etching apparatus,
LU—Loader/Unloader
AT—Air transfer chamber,
RA—Robot arm,
VT—Vacuum transfer chamber,
EC—Etching chamber,
AC—Ashing chamber,
UM—Upper matching box,
LM—Lower matching box,
AP—Automatic pressure control valve (APC),
TM—Turbo molecular pump (TMP),
RA—High frequency antenna, and
RI—High frequency introducing window.

What is claimed is:

1. A semiconductor manufacturing apparatus comprising:
a suction head on which a wafer is mounted; and
a protection ring installed so as to surround a circumference of the suction head,
wherein the suction head includes a base and a stage that is bonded onto the base with an epoxy resin, and a distance from the stage to the protection ring is smaller than a mean free path of molecules in plasma.

2. The semiconductor manufacturing apparatus according to claim 1,
wherein the protection ring has a lower region whose end is close to the suction head and an upper region whose end is more distant from the suction head than the lower region, and a distance from the wafer to a surface of the lower region when the wafer is mounted on the suction head is smaller than the mean free path of the molecules in the plasma.

3. The semiconductor manufacturing apparatus according to claim 1,
wherein the protection ring has a lower region whose end is close to the suction head and an upper region whose end is more distant from the suction head than the lower region, and when the wafer is mounted on the suction head, drawing a virtual straight line that connects an end of the upper region on its uppermost surface facing the suction head, an end of the wafer, and the epoxy region, the virtual straight line is obstructed by the lower region.

4. The semiconductor manufacturing apparatus according to claim 2,
wherein the stage has a concave part on its side face facing the protection ring, and a part of the lower region extends in the concave part.

5. The semiconductor manufacturing apparatus according to claim 1,
wherein the protection ring has a lower region whose end is close to the suction head, an intermediate region whose end is more distant from the suction head than the lower region, and an upper region whose end is more distant from the suction head than the intermediate region, and an end of the stage is located between an end of the lower region and an end of the intermediate region.

6. The semiconductor manufacturing apparatus according to claim 5,
wherein the protection ring can be divided into at least two parts.

7. The semiconductor manufacturing apparatus according to claim 1,
wherein the semiconductor manufacturing apparatus is any one of a dry etching apparatus, a plasma CVD apparatus, or a sputtering apparatus.

8. The semiconductor manufacturing apparatus according to claim 1,
wherein the protection ring is made of quartz.

9. A method for manufacturing a semiconductor integrated circuit device comprising the steps of:
(a) forming a film to be processed on a principal plane of a semiconductor substrate;
(b) applying a photoresist film to the film to be processed;
(c) transferring a predetermined circuit pattern to the photoresist film by photolithography to form a mask pattern; and
(d) performing dry etching processing on the film to be processed and the mask pattern using a dry etching apparatus such that a distance from a stage of a suction head to a protection ring is smaller than a mean free path of molecules in plasma.

10. The method for manufacturing a semiconductor integrated circuit device according to claim 9,
wherein the protection ring has a lower region whose end is close to the suction head and an upper region whose end is more distant from the suction head than the lower region, and when a wafer is mounted on the suction head,
a distance from the wafer to a surface of the lower region is smaller than the mean free path of the molecules in the plasma.

11. The method for manufacturing a semiconductor integrated circuit device according to claim 9,
wherein the protection ring has a lower region whose end is close to the suction head and an upper region whose end is more distant from the suction head than the lower region, and when a wafer is mounted on the suction head, drawing a virtual straight line that connects an end of the upper region on its uppermost surface facing the suction head, an end of the wafer, and an epoxy resin for bonding the stage to a base, the virtual straight line is obstructed by the lower region.

12. The method for manufacturing a semiconductor integrated circuit device according to claim 9,
wherein the stage has a concave part on its side face facing the protection ring, and a part of the lower region extends in the concave part.

13. The method for manufacturing a semiconductor integrated circuit device according to claim 9,
wherein the protection ring has a lower region whose end is close to the suction head, an intermediate region whose end is more distant from the suction head than the lower region, and an upper region whose end is more distant from the suction head than the intermediate region, and an end of the stage is located between the end of the lower region and the end of the intermediate region.

14. The method for manufacturing a semiconductor integrated circuit device according to claim 13,
wherein the protection ring can be divided into at least two parts.

15. The method for manufacturing a semiconductor integrated circuit device according to claim 9,
wherein the film to be processed is any one of a polysilicon film, a silicon oxide film, or an aluminum film.
